(19) United States
(12) Patent Application Publication
(10) Pub. No.: US 2025/0254803 A1
(43) Pub. Date: Aug. 7, 2025

(54) FOLDABLE DISPLAY DEVICE

(71) Applicant: LG Display Co., Ltd., Seoul (KR)

(72) Inventors: Suk CHOI, Hwaseong-si (KR); HyeRan PARK, Goyang-si (KR); MinHo LEE, Geoje-si (KR)

(73) Assignee: LG Display Co., Ltd., Seoul (KR)

(21) Appl. No.: 19/045,243

(22) Filed: Feb. 4, 2025

(30) Foreign Application Priority Data
Feb. 5, 2024 (KR) 10-2024-0017674

(51) Int. Cl. H05K 5/02

(52) U.S. Cl. CPC H05K 5/02

(57) ABSTRACT

A foldable display device can include a display panel having a fold area, a plate bottom supporting the display panel from a lower portion of the display panel and having a plurality of opening patterns corresponding to the fold area, a back plate disposed between the display panel and the plate bottom, and a black coating layer disposed on at least one surface of the back plate. The black coating layer includes a first carbon black particle having an average particle size of less than 2 um, a second carbon black particle having an average particle size ranging from 2 um to less than 5 um, and a third carbon black particle having an average particle size of 5 um or greater.

### CROSS-REFERENCE TO RELATED APPLICATIONS

This application claims priority to Korean Patent Application No. 10-2024-0017674 filed on Feb. 5, 2024, in the Korean Intellectual Property Office, the entire contents of which is hereby expressly incorporated by reference into the present application.

### BACKGROUND

### Field

The present disclosure relates to a foldable display device, and particularly, a foldable display device that secures improvement in exterior quality and reliable folding.

### Discussion of the Related Art

In the information era, display devices for visually displaying electric information signals have recently been developed rapidly. In response, various types of display devices providing excellent performance, such as a display device that is thin and lightweight and consumes less power, have been developed. Display devices can include a liquid crystal display (LCD) device, a plasma display panel (PDP) device, a field emission display (FED) device, an organic light emitting display (OLED) device, and the like.

In recent years, flexible display devices that can display an image even when they are bent or folded like paper have drawn attention as a next-generation display device. Flexible display devices can be divided into an unbreakable display device that ensures high durability, a bendable display device that is unbreakable and bendable, a rollable display device that is rollable, a foldable display device that is foldable, and the like, and can have advantages in spatial availability, interior and design and can be applied to a variety of fields.

Additionally, since a flexible display device such as a foldable display device needs to be folded and unfolded, a plate bottom having a plurality of opening patterns in a fold area is disposed under the display panel, to support the display panel and secure flexibility for embodying a target radius of curvature. However, the opening patterns are viewed by a user, which can cause deterioration in exterior quality.

Further, in the case where an additional member is provided to prevent the opening patterns from being visible, a plurality of adhesive layers is disposed to bond each layer. As a result, however, the entire thickness of the foldable display device can increase, so that stress applied to the plate bottom and other elements can increase at a time of folding, which can cause deterioration in reliable folding.

### SUMMARY OF THE DISCLOSURE

One objective of the present disclosure is to provide a foldable display device that can prevent opening patterns from being viewed.

Another objective of the present disclosure is to provide a foldable display device that can secure a reduction in the reflection of external light and an excellent visual sensation of black.

Yet another objective of the present disclosure is to provide a foldable display device that can ensure improvement in heat dissipation properties.

Objects of the present disclosure are not limited to the above-mentioned objects, and other objects, which are not mentioned above, can be clearly understood by those skilled in the art from the following descriptions.

A foldable display device according to one embodiment of the present disclosure comprises a display panel configured to comprise a fold area, a plate bottom configured to comprise a fold area, a plate bottom configured to support the display panel from a lower portion of the display panel and to comprise a plurality of opening patterns corresponding to the fold area, a back plate disposed between the display panel and the plate bottom, and a black coating layer disposed on at least one surface of the back plate and configured to comprise a first carbon black particle having an average particle size of less than 2 um, a second carbon black particle having an average particle size of 2 um or greater and less than 5 um, and a third carbon black particle having an average particle size of 5 um or greater.

Other detailed matters of the example embodiments of the present disclosure are included in the detailed description and the drawings.

According to aspects of the present disclosure, the coating layer comprising carbon black particles having a different particle size is used, thereby reducing the visibility of the opening patterns of the plate bottom and securing improvement in exterior quality.

According to aspects of the present disclosure, the reflection of external light decreases, thereby securing improvement in a visual sensation of black.

According to aspects of the present disclosure, an aggregate of carbon black particles is used, thereby securing improvement in heat dissipation properties.

According to aspects of the present disclosure, recycled carbon black and bio carbon black are used as a carbon black particle, thereby increasing an eco-friendly ratio.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a foldable display device according to one embodiment of the present disclosure;

FIG. 2 is a schematic cross-sectional view along line I-I′ of FIG. 1;

FIG. 3 is a schematic cross-sectional view of a foldable display device according to another embodiment of the present disclosure;

FIG. 4 is a schematic cross-sectional view of a foldable display device according to another embodiment of the present disclosure;

FIG. 5 is a schematic cross-sectional view of a foldable display device according to another embodiment of the present disclosure; and

FIG. 6 is a schematic cross-sectional view of a foldable display device according to yet another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure.

Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure. Further, the term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a foldable display device according to example embodiments of the present disclosure will be described in detail with reference to accompanying drawings. All the components of each display device according to all embodiments of the present disclosure are operatively coupled and configured.

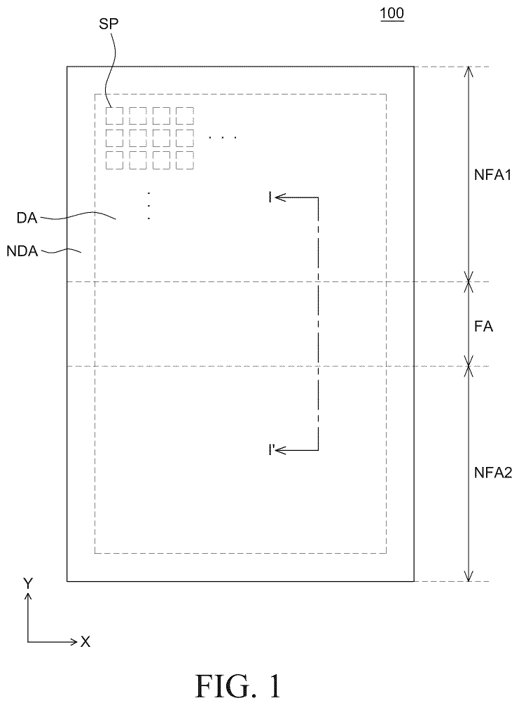

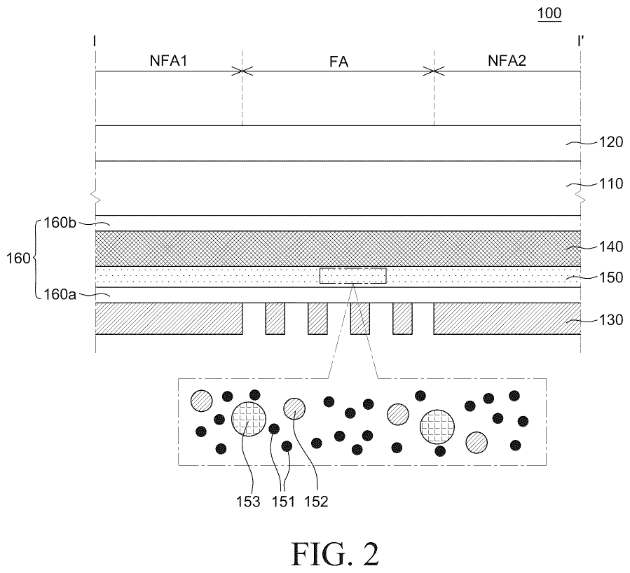

FIG. 1 is a schematic plan view of a foldable display device according to one embodiment of the present disclosure. FIG. 2 is a schematic cross-sectional view along line I-I′ of FIG. 1.

Referring to FIGS. 1 and 2, a foldable display device 100 according to one embodiment comprises a display panel 110, cover window 120, a plate bottom 130, a back plate 140, a black coating layer 150 and an adhesive layer 160. Hereinafter, for convenience of description, suppose that the foldable display device 100 of one embodiment is an organic light emitting display device, but the foldable display device 100 is not limited thereto.

The display panel 110 comprises a display area DA (or active area) and a non-display area NDA (or non-active area). The non-display area NDA can surround the display area DA entirely or only in part(s). Additionally, the display panel 110 comprises a fold area FA and non-fold areas NFA1, NFA2. The display panel 110 can be divided into a display area DA and a non-display area NDA depending on whether an image is displayed or not. Additionally, the display panel 110 can be divided into a fold area FA and non-fold areas NFA1, NFA2 depending on whether to be folded or not. Accordingly, a partial area of the display panel 110 can be a fold area FA as well as a display area DA, and the remaining area of the display panel 110 can be a non-fold area NFA1, NFA2 as well as a non-display area NDA.

Further, hereinafter, suppose that the foldable display device 100 of one embodiment is a foldable display device in which one fold area FA is disposed only in a portion of the display area DA, for convenience of description. However, the foldable display device 100 of one embodiment can be a display device in which a plurality of fold areas is disposed in the display area DA of the display panel 110, and not limited thereto.

The display area DA is an area in which a plurality of pixels is disposed and an image is substantially displayed. In the display area DA, a plurality of pixels comprising a light emitting area for displaying an image, a thin film transistor for driving the pixels, a capacitor and the like can be disposed. One pixel can comprise a plurality of sub pixels SP. The sub pixel SP as a minimum unit constituting the display area can respectively be configured to emit light of a specific wavelength band. For example, each sub pixel SP can be configured to emit red light, green light, blue light or white light.

The non-display area NDA is disposed to surround the display area DA. The non-display area NDA is an area where an image is not substantially displayed, and in the non-display area NDA, a variety of lines, driving integrated circuits (ICs) and the like for driving pixels and driving elements disposed in the display area DA are disposed.

As described above, the display panel 110 can also be defined as a fold area FA and non-fold areas NFA1, NFA2 depending on whether the display panel 110 is folded or not. The display panel 110 comprises one fold area FA that is foldable, and non-fold areas NFA1, NFA2 that exclude the fold area FA. The fold area FA, as an area that is folded in the case where the foldable display device 100 is folded, can be folded according to a specific radius of curvature with respect to a fold axis. Herein, the fold axis can be formed in an X-axis direction. The non-fold areas NFA1, NFA2 can be placed at both sides of the fold area FA along a fold direction. Herein, the fold direction can denote a Y-axis direction perpendicular to the fold axis. In the case where the fold area FA is folded with respect to the fold axis, the fold area FA can form a portion of a circle or an oval. At this time, the radius of curvature of the fold area FA denotes the radius of a circle or an oval formed by the fold area FA.

The non-fold areas NFA1, NFA2 are areas that are not folded in the case where the foldable display device 100 is folded. For example, the non-fold areas NFA1, NFA2 remain planar in the case where the foldable display device 100 is folded. The non-fold areas NFA1, NFA2 can extend from both sides of the fold area FA along the fold direction. At this time, the fold area FA can be defined between the non-fold areas NFA1, NFA2. The non-fold areas NFA1, NFA2 comprise a first non-fold area NFA1 and a second non-fold area NFA2. The first non-fold area NFA1 can extend from one side of the fold area FA, and the second non-fold area NFA2 can extend from the other side of the fold area FA. In the case where the foldable display device 100 is folded with respect to the fold axis, the first non-fold area NFA1 and the second non-fold area NFA2 can overlap each other.

The display panel 110 comprises a flexible substrate, a driving thin film transistor, a display element and the like. The display panel 110 can be the one that is formed in such a way that a flexible substrate, on which a driving thin film transistor, a display element and the like are formed, is encapsulated by an encapsulation part. To embody flexibility, the display panel 110 comprises a flexible substrate that is thin, and a display element that is disposed on the flexible substrate.

The flexible substrate supports a variety of elements constituting the display panel 110. The flexible substrate can be formed of an insulation material that is very thin in its thickness, to embody flexibility. For example, the flexible substrate can be a plastic insulating substrate of a material selected from polyimide, polyethersulfone, polyethylene terephthalate and polycarbonate, but not limited thereto.

A driving thin film transistor for driving a display element can be disposed on the flexible substrate. The driving thin film transistor can be disposed in each of the plurality of pixels. For example, the driving thin film transistor comprises a gate electrode, an active layer, a source electrode and a drain electrode. Additionally, the driving thin film transistor can further comprise a gate insulation layer for insulating the gate electrode and the active layer, and can further comprise an interlayer insulation layer for insulating the gate electrode from the source electrode and the drain electrode.

The display element can be an organic light emitting element. The organic light emitting element can comprise an anode, a cathode and an organic light emitting layer disposed between the anode and the cathode. The organic light emitting element emits light in such a way that holes injected from the anode and electrodes injected from the cathode are coupled in the organic light emitting layer. With the light emitted as described above, an image can be displayed.

A cover window 120 is disposed on the display panel 110. The cover window 120 protects the display panel 110 from an external shock and a scratch. Accordingly, the cover window 120 can be formed of a material that is transparent and excellently resistant against a shock and a scratch. Additionally, the cover window 120 protects the display panel 110 from moisture and the like infiltrating from the outside. Thus, the cover window 120 can prevent the deterioration of display quality caused by the degradation of the display panel 110.

The cover window 120 can be embodied as a cover based on ductile plastic that is foldable to secure a foldable display device 100 which is thin and flexible. For example, the cover window 120 can be a film made of a polymer such as polyimide, polyamide imide, polyethyleneterephthalate, polyethylenemethacrylate, propylene glycol, polycarbonate and the like. Alternatively, the cover window 120 can be a film made of an optically isotropic polymer such as a cycloolefin (co) polymer, optically isotropic polycarbonate, optically isotropic polymethacrylate and the like.

The cover window 120 can have a multi-layer structure in which various types of functional layers are stacked. For example, the cover window 120 can comprise a variety of functional layers such as an external light reflection reducing layer, a UV blocking layer, a hard coating layer, and the like. Additionally, a touch panel constituting a touch sensor can be selectively disposed between the display panel 110 and the cover window 120, when necessary.

Further, the flexible substrate of the display panel 110 has excellent folding properties, but is thin and is less stiff than a glass substrate or a metal substrate. Accordingly, the shape of the flexible substrate can hardly be kept constant, and can sag due to a variety of elements formed thereon, at a time when the substrate is folded. In this regard, a plate bottom 130 and a back plate 140 are disposed under the display panel 110 to support the flexible substrate and enhance resistance against a shock. The plate bottom 130 and the back plate 140 can support the display panel 100 from the lower portion of the display panel 110 to prevent a sag or deformation, and protect the display panel 110 from an external shock or foreign substances.

The plate bottom can be referred to as a bottom plate or a cover bottom. The plate bottom 130 can be a plate having foldability and excellent stiffness. The plate bottom 130 can formed of a material that is stiffer than that of the flexible substrate to support the display panel 110.

The plate bottom 130 can be made of a metallic material such as stainless steel (SUS), stainless steel (SUS) comprising metal such as nickel (Ni) and the like, iron (Fe), an aluminum (Al) group or magnesium (Mg). It can be preferable to apply stainless steel (SUS) as a material for the plate bottom 130. For example, since stainless steel (SUS) has high restoring force and high stiffness, the plate bottom 130 can maintain high stiffness even if the thickness of the plate bottom 130 decreases. Accordingly, the plate bottom 130 can help to reduce the entire thickness of the foldable display device 100, thereby reducing the radius of curvature of the fold area FA, while supporting the display panel 110. However, the plate bottom 130 is not limited to the above-described one, and can be made of a macromolecule such as polymethylmetacrylate (PMMA), polycarbonate (PC), polyvinylalcohol (PVA), acrylonitirle-butadiene-styreneb (ABS), polyethylene terephthalate (PET), silicone, and polyurethane (PU).

The thickness of the plate bottom 130 can be from 90 μm to 220 μm. In the case where the plate bottom 130 has a thickness of less than 90 μm, the plate bottom 130 can be too thin to support the display panel 110 effectively and can sag. Additionally, in the case where the plate bottom 130 has a thickness of 220 μm or greater, stress applied to the display panel 110 and the like can increase, forming a crack, and the restoring force can decrease, causing plastic deformation, at a time when the foldable display device 100 is folded, and as a result, reliable folding may not be secured.

The plate bottom 130 can comprise a plurality of opening patterns 131 formed to correspond to the fold area FA of the foldable display device 100. In the fordable display device 100, an elastic deformation section is increased by the plurality of opening patterns 131 formed in the fold area FA, so that the foldable display device 100 can be folded or unfolded. In FIG. 2, five opening patterns 131 are formed for convenience of description, but not limited.

The plurality of opening patterns 131 can be formed at the plate bottom 130, to correspond to the fold area FA. For example, the plurality of opening patterns 131 can be a hole that is formed by penetrating the plate bottom 130 in the thickness-wise direction thereof. In the case where the foldable display device 100 is folded, stress concentrates on the fold area FA. The plurality of opening patterns 131 can disperse the stress concentrating on the fold area FA at a time of folding. As described above, since the plurality of opening patterns 131 is formed at a position corresponding to the fold area FA, the foldable display device 100 can be readily folded and restored.

Each of the plurality of opening patterns 131 can be elongated along a direction parallel with the fold axis. For example, each of the plurality of opening patterns 131 can be elongated along a direction identical with the fold axis. Accordingly, each of the plurality of opening patterns 131 can be formed in parallel with the fold axis, in the form of a bar on a plan view. Further, each of the plurality of opening pattens 131 can be elongated continuously up to the non-display area, across the display area DA, along a direction the same as the fold axis, without being disconnected, but not limited thereto.

Further, a plate top or a top plate can be disposed on the plate bottom 130. The plate top can enhance the stiffness of the display panel 110, and the plurality of opening pattens 131 formed at the plate bottom 130 can be prevented from being viewed through the display panel 110. At this time, the plate top can be made of a metallic material such as stainless steel (SUS), stainless steel (SUS) comprising metal such as nickel (Ni) and the like, iron (Fe), an aluminum (Al) group or magnesium (Mg). However, the plate top is not limited to the above-described one, and the plate top can be made of a macromolecule such as polymethylmetacrylate (PMMA), polycarbonate (PC), polyvinylalcohol (PVA), acrylonitirle-butadiene-styrene (ABS), polyethylene terephthalate (PET), silicone, and polyurethane (PU). Additionally, the plate top can be made of the same material as the plate bottom 130, but not limited thereto.

The back plate 140 can be disposed between the display panel 110 and the plate bottom 130. The back plate 140 can be attached to the back surface of the display panel 110 to further support the display panel 110 that is thin, but when necessary, can be excluded. The back plate 140 can prevent the plurality of opening patterns 131 provided at the plate bottom 130 from being viewed through the display panel 110.

The back plate 140 can be made of a macromolecule such as polyimide (PI), polymethylmetacrylate (PMMA), polycarbonate (PC), polyvinylalcohol (PVA), acrylonitirle-butadiene-styrene (ABS), polyethylene terephthalate (PET), silicone, and polyurethane (PU), but not limited thereto.

The back plate 140 can be made of bio resin. The bio resin can be resin that is made of environmentally friendly resin or a recycled resource which is manufactured by polymerizing lactic acid, ethanol, or propanol manufactured by fermenting recyclable plant resources such as corn, potatoes and the like. The bio resin emits much less materials harmful to the environment, such as CO2 and the like, than a petroleum-based material such as polyvinyl chloride (PVC) and the like, during use or waste, and is readily decomposed in the natural environment and environmentally friendly, during waste. The bio resin can be manufactured solely by using a variety of bio resins such as PLA (poly lactic acid), BIO-PU (polyurethane), BIO-PET (polyethylene terephthalate), BIO-PPT (polypropylene terephthalate), BIO-PE (polyethylene) and BIO-PP (polypropylene) or by mixing two or more sorts thereof.

The black coating layer 150 can be disposed on at least one surface of the back plate 140. For example, the black coating layer 150 can be disposed between the plate bottom 130 and the back plate 140, and disposed to contact the lower surface of the back plate 140. The black coating layer 150 can prevent the opening patterns 131 formed at the plate bottom 130 disposed under the black coating layer 150 from being transferred to an element on the black coating layer 150 and viewed by the user' eyes. Additionally, the black coating layer 150 can reduce the reflection of external light and embody a visual sensation of neutral black. Additionally, the black coating layer 150 can enhance heat dissipation performance.

The black coating layer 150 comprises a base resin, a first carbon black particle 151, a second carbon black particle 152 and a third carbon black particle 153.

The base resin, as a material formed from a binder compound, is a base material constituting the black coating layer 150. The base resin 142 can be formed based on the polymerization of a binder compound. The binder compound forming the base resin 142 can be a thermosetting or thermoplastic macromolecule. For example, the thermosetting macromolecule can be a compound of one sort selected from a group comprised of an epoxy, urethane, ester and polyimide-based resin, or a mixture or a copolymer of two or more sorts thereof. Additionally, the thermoplastic macromolecule can be a compound of one sort selected from a group comprised of polyamide (PA), polyester, polyketone, polyolefine, polyphenylenesulfide (PPS), polyetheretherketone (PEEK), polyphenyleneoxide (PPO), polyethersulfone (PES), polyetherimide (PEI) and polyimide, or a mixture or a copolymer of two or more sorts thereof, but not limited thereto. At this time, the binder compound is polyimide or polyamide having excellent stiffness and heat dissipation properties. The base resin 142 can be a high molecular compound based on polyimide or polyamide.

The first carbon black particle 151 has an average particle size of less than 2 um. The second carbon black particle 152 has an average particle size of 2 um or greater and less than 5 um. The third carbon black particle 153 has an average particle size of 5 um or greater.

The first carbon black particle 151, the second carbon black particle 152 and the third carbon black particle 153 reduce external reflection, enhance a visual sensation of black, and prevent the opening patterns 131 formed at the plate bottom 130 disposed under the black coating layer from being viewed by the user's eyes. Further, unless stated otherwise in this disclosure, the average particle size denotes a particle size (D50) corresponding to 50% in an accumulated particle size distribution.

Specifically, the first carbon black particle 151 has a small particle size, fills a vacant space between the second carbon black particle 152 and the third carbon black particle 153 in the black coating layer 150, and enhances the durability of the black coating layer 150.

At this time, the first carbon black particle 151 comprises a 1-1 carbon black particle and a 1-2 carbon black particle. The 1-1 carbon black particle has an average particle size of less than 1 um or 1 nm to 300 nm. The 1-1 carbon black particle can be a carbon particle having a unimolecular structure. For example, acetylene black, furnace black, ketjen black and the like can be referred to as carbon black. The 1-1 carbon black particle can be formed in a thermal decomposition process. The 1-1 carbon black particle can be a hollow particle of which is substantially vacant as the core portion. A hollow carbon black, for example, can have density of 0.60 g/cm³ to 0.90 g/cm³ or 0.70 g/cm³ to 0.80 g/cm³. Further, the 1-1 carbon black particle can be surface-modified with a carboxy group (—COOH), a hydroxy group (—OH), or a sulfonic group (—SO₃H).

The 1-2 carbon black particle has an average particle size of 1 um to 3 um or 1 um or greater and less than 2 um. The 1-2 carbon black particle can be an aggregate where carbon black particles are aggregated mutually because of a high surface area of the carbon black particle. For example, the 1-2 carbon black particle can be an aggregate where a plurality of 1-1 carbon black particles is aggregated.

The 1-2 carbon black particle can be mixed or additionally aggregated with a conductive compound. For example, the 1-2 carbon black particle can be mixed or aggregated with poly 3,4-ethylenedioxythiophene (PEDOT) that is a conductive macromolecule or carbon nano tube that is a thermally conductive material. Additionally, thermally conductive materials can use one or more sorts selected from power of metal such as aluminum (Al), nickel (Ni), copper (Cu), tin (Sn), zinc (Zn), tungsten (W), iron (Fe), silver (Ag), gold (Au) and the like, powders of an inorganic material such as calcium carbonate (CaCO3), aluminum oxide (Al2O3), aluminum hydroxide (Al(OH)3), silicon carbide (SiC), boron nitride (BN), aluminum nitride (AlN) and the like, or powders of an organic material such as graphite, graphene, carbon nanotubes (CNT), carbon nanofibers (CNF) and the like that are carbon materials, and the like. At this time, the 1-2 carbon black particle has a heat dissipation property, so that heat generated from the display panel 110 disposed in the upper portion of the display device can be readily dissipated outward through the plate bottom 130 disposed in the lower portion of the display device.

The second carbon black particle 152 can have an average particle size of 2 um to 7 um or 2 um or greater and less than 5 um. The second carbon black particle 152 can increase the thickness of the black coating layer 150, enhance the roughness Ra of the black coating layer 150, and decrease reflectance.

The second carbon black particle 152 can be an aggregate where carbon black particles are aggregated mutually because of a high surface area of the carbon black particle. For example, the second carbon black particle 152 can comprise recycled carbon black obtained from carbon black containing products such as a disused tire that is no longer used. The recycled carbon black can be typically obtained in a recycling process entailing a thermal decomposition process for decomposing an organic ingredient such as rubber or plastic or a desalting process for dissolving an inorganic additive or impurities. The second carbon black particle 152 as recycled carbon black can further comprise impurities. For example, the second carbon black particle 152 can comprise at least one of impurities comprised of silicon dioxide, zinc oxide and calcium carbonate.

The third carbon black particle 153 has an average particle size of 5 um or greater or 5 um to 7 um. The third carbon black particle 153 can increase the thickness of the black coating layer 150, enhance the roughness Ra of the black coating layer 150, and decrease reflectance.

The third carbon black particle 153 can be an aggregate where carbon black particles are aggregated mutually because of a high surface area of the carbon black particle. For example, the third carbon black particle 153 can comprise bio carbon black that is generated by carbonizing a natural bio material or a natural lignocellulosic material. Bio carbon black can be obtained by thermally decomposing a natural bio material or a natural lignocellulosic material comprising any one or more of flax, hemp, jute, kenaf, abaca, bamboo, coir, palm, a coconut skin, a pineapple skin, ramie, sisal, henequen, ginseng, rice straws, chaff, wood powder, and green tea. Bio carbon black can comprise carbon-14 (C14).

A total content of the first carbon black particle 151, the second carbon black particle 152 and the third carbon black particle 153 can be 50 wt % to 95 wt % or 60 wt % to 90 wt % with respect to the entire weight of the black coating layer 150. In the case where the total content of the first carbon black particle 151, the second carbon black particle 152 and the third carbon black particle 153 satisfies the above-described range, the black coating layer 150 can have sufficient roughness Ra, so that the plurality of opening patterns 131 provided at the plate bottom 130 under the black coating layer 150 is prevented from being viewed.

Further, with respect to the entire weight of the solid content of the first carbon black particle 151, the second carbon black particle 152 and the third carbon black particle 153, 10 wt % to 50 wt % of the first carbon black particle 151 can be included, 25 wt % to 65 wt % of the second carbon black particle 152 can be included, and 25 wt % to 65 wt % of the third carbon black particle 153 can be included.

In the case where the content of the first carbon black particle 151, the second carbon black particle 152 and the third carbon black particle 153 satisfies the above-described range, the roughness Ra of the black coting layer 150 can improve, so that the visibility of the plurality of opening patterns 131, provided at the plate bottom 130 under the black coting layer 150, from above is suppressed, and a visual sensation of neutral black close to reflection chroma of a*=0 and b*=0 is displayed based on an a*b* color coordinate. At this time, in the case where the content of the second carbon black particle 152 and the content of the third carbon black particle 153 are respectively 30 wt % or greater, the roughness Ra of the black coating layer 150 can improve further.

The thickness of the black coating layer 150 can be 8 um to 15 um or 10 um to 13 um. In the case where the thickness of the black coating layer 150 satisfies the above-described range, the plurality of opening patterns 131 provided at the plate bottom 130 disposed under the black coating layer 150 can be prevented from being viewed. Additionally, the thickness of the black coating layer 150 can be determined based on the sizes and content of the first carbon black particle, the second carbon black particle 152 and the third carbon black particle 153. For example, in the case where total mass of the second carbon black particle 152 and the third carbon black particle 153 is 50 wt % or greater with respect to the mass of the entire carbon black particle, the above-described thickness can be satisfied.

The roughness Ra of the black coating layer 150 can be 1.0 um or greater or 1.5 um to 3 um. In the case where the roughness Ra of the black coating layer 150 satisfies the above-described range, the visibility of the plurality of opening patterns 131 provided at the plate bottom 130 disposed under the black coating layer 150 can be suppressed.

The plate bottom 130, the back plate 140 and the display panel 110 are attached through at least one adhesive layer 160. Referring to FIG. 2, the adhesive layer 160 comprises a first adhesive layer 160a and a second adhesive layer 160b. The first adhesive layer 160a can be disposed on the plate bottom 130, and attach the plate bottom 130 and the back plate 140. In FIG. 2, since the black coating layer 150 is disposed on the lower surface of the back plate 140, the first adhesive layer 160a can be disposed between the plate bottom 130 and the black coating layer 150. The second adhesive layer 160b can be disposed on the back plate 140 and attach the back plate 140 and the display panel 110.

The adhesive layer 160 can be selected from a resin composition constituting an optical clear adhesive (OCA), an optical clear resin (OCR) and a pressure sensitive adhesive (PSA), but not limited thereto. Specifically, the adhesive layer 160 can be comprised of a pressure sensitive adhesive (PSA) capable of providing adhesion and elasticity to maintain the folding properties of the foldable display device 100. For example, the adhesive layer 160 can be comprised of acryl-based resin, acrylate-based resin, epoxy-based resin, polyimide-based resin, vinyl-based resin and the like that have adhesion.

The flexible display device of one embodiment comprises a black coating layer where carbon black particles are included between a bottom plate comprising a plurality of opening pattens corresponding to the fold area and a back plate. The black coating layer comprises a first carbon black particle having an average particle size of less than 2 um, a second carbon black particle having an average size of 2 um or greater and less than 5 um, and a third carbon black particle having an average size of 5 um or greater. The thickness and roughness of the black coating layer can be adjusted based on a combination of carbon black particles having a specific average particle size, and accordingly, the opening patterns formed at the plate bottom disposed under the black coating layer can be prevented from being viewed by the user's eyes. Additionally, the black coating layer can reduce the reflection of external light and prevent deterioration in the visual sensation of black.

Additionally, in the case of a flexible display device of one embodiment, recycled carbon black can be used as the second carbon black particle 152, and bio carbon black can be used as the third carbon black particle 153, thereby increasing an eco-friendly ratio and contributing to environmental protection.

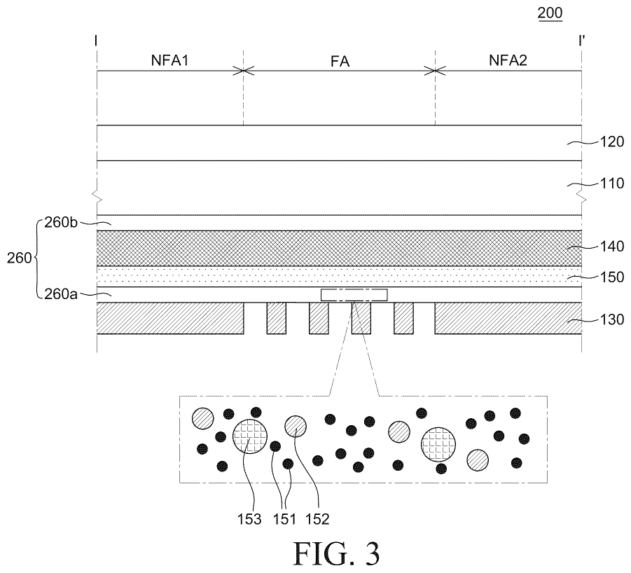

FIG. 3 is a schematic cross-sectional view of a foldable display device according to another embodiment of the present disclosure.

Referring to FIG. 3, a foldable display device 200 in this embodiment comprises a display panel 110, a cover window 120, a plate bottom 130, a back plate 140, a black coating layer 150 and an adhesive layer 260. The fordable display device 200 illustrated in FIG. 3 is substantially the same as the foldable display device 100 illustrated in FIG. 2, except that a first carbon black particle 151, a second carbon black particle 152 and a third carbon black particle 153 are included in a first adhesive layer 260a, and accordingly, their common features are not described or may be briefly described.

In the foldable display device 200, the first adhesive layer 260a disposed between the black coating layer 150 and the plate bottom 130 comprises the first carbon black particle 151, the second carbon black particle 152, and the third carbon black particle 153, like the black coating layer 150. At this time, the first carbon black particle 151, the second carbon black particle 152, and the third carbon black particle 153 included in the first adhesive layer 260a can be identical with or different from the first carbon black particle 151, the second carbon black particle 152, and the third carbon black particle 153 included in the black coating layer 150. Since the first carbon black particle 151, the second carbon black particle 152, and the third carbon black particle 153 included in the first adhesive layer 260a are substantially the same as those described with reference to FIG. 2, the carbon black particles are not described.

In the foldable display device 200, the first carbon black particle 151, the second carbon black particle 152, and the third carbon black particle 153 are further added to the first adhesive layer 260a placed under the black coating layer 150 comprising the first carbon black particle 151, the second carbon black particle 152, and the third carbon black particle 153, so that the first adhesive layer 260a together with the black coating layer 150 can further prevent the opening patterns under the black coating layer 150 from being viewed.

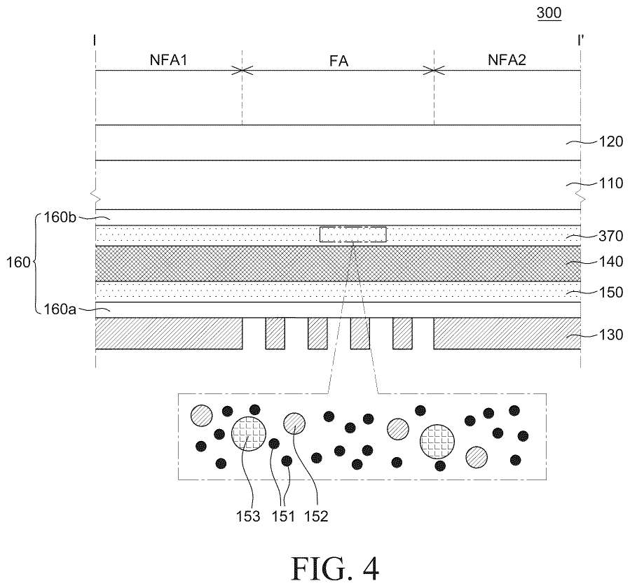

FIG. 4 is a schematic cross-sectional view of a foldable display device according to another embodiment of the present disclosure.

Referring to FIG. 4, a foldable display device 300 in this embodiment comprises a display panel 110, a cover window 120, a plate bottom 130, a back plate 140, a black coating layer 150, an adhesive layer 160, and a subsidiary black coating layer 370. The foldable display device 300 illustrated in FIG. 4 is substantially the same as the foldable display device 100 illustrated in FIG. 2 except that the foldable display device 300 further comprises the subsidiary black coating layer 370 on the back plate 140, and accordingly, their common features are not described or may be briefly described.

In the foldable display device 300, the subsidiary black coating layer 370 disposed on the back plate 140, like the black coating layer 150 disposed under the back plate 140, comprises a first carbon black particle 151, a second carbon black particle 152 and a third carbon black particle 153. At this time, the first carbon black particle 151, the second carbon black particle 152 and the third carbon black particle 153 included in the subsidiary black coating layer 370 can be identical with or different from the first carbon black particle 151, the second carbon black particle 152 and the third carbon black particle 153 included in the black coating layer 150. Since the first carbon black particle 151, the second carbon black particle 152 and the third carbon black particle 153 included in the subsidiary black coating layer 370 are substantially the same as those described with reference to FIG. 2, the carbon black particles area not described or may be briefly described.

In the foldable display device 300, the first carbon black particle 151, the second carbon black particle 152, and the third carbon black particle 153 are further added to the subsidiary black coating layer 370 placed on the black coating layer 150 comprising the first carbon black particle 151, the second carbon black particle 152, and the third carbon black particle 153, so that the subsidiary black coating layer 370 together with the black coating layer 150 can further prevent the opening patterns under the black coating layer 150 from being viewed.

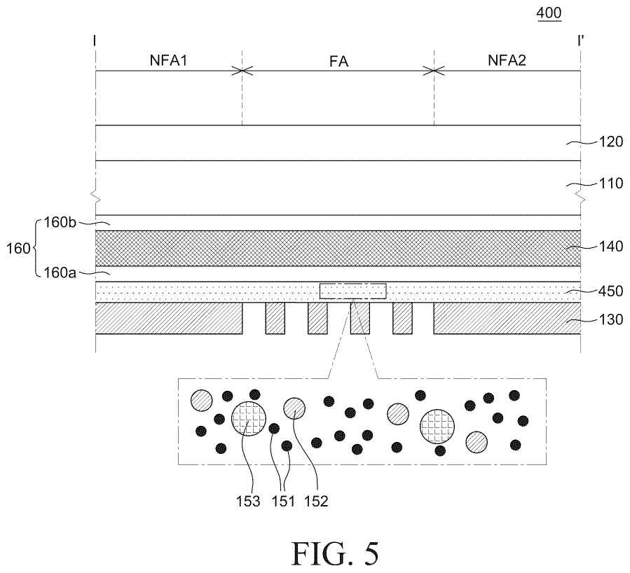

FIG. 5 is a schematic cross-sectional view of a foldable display device according to another embodiment of the present disclosure.

Referring to FIG. 5, a foldable display device 400 in this embodiment comprises a display panel 110, a cover window 120, a plate bottom 130, a back plate 140, a black coating layer 450, and an adhesive layer 160. The foldable display device 400 illustrated in FIG. 5 is substantially the same as the foldable display device 100 illustrated in FIG. 2 except that the position of the black coating layer 450 differs, and accordingly, their common features are not described or may be briefly described.

In the foldable display device 400, the adhesive layer 160 comprises a first adhesive layer 160a disposed under the back plate 140 and a second adhesive layer 160b disposed on the back plate 140. At this time, the black coating layer 450 is disposed under the first adhesive layer 160a, to contact the plate bottom 130 directly.

The black coating layer 450 can be formed in such a way that a composition comprised of the base resin, the first carbon black particle 151, the second carbon black particle 152 and the third carbon black particle 153 is coated directly on the plate bottom 130. In the fordable display device 400 of another embodiment, the black coating layer 450 for preventing the opening patterns under the black coating layer 450 from being viewed is disposed directly on the plate bottom 130, so that the opening patterns are prevented from being viewed regardless of the positions of the other elements. Further, in FIG. 5, the first adhesive layer 160a is disposed on the black coating layer 450, and in some cases, can be omitted, and the back plate 140 can also be omitted.

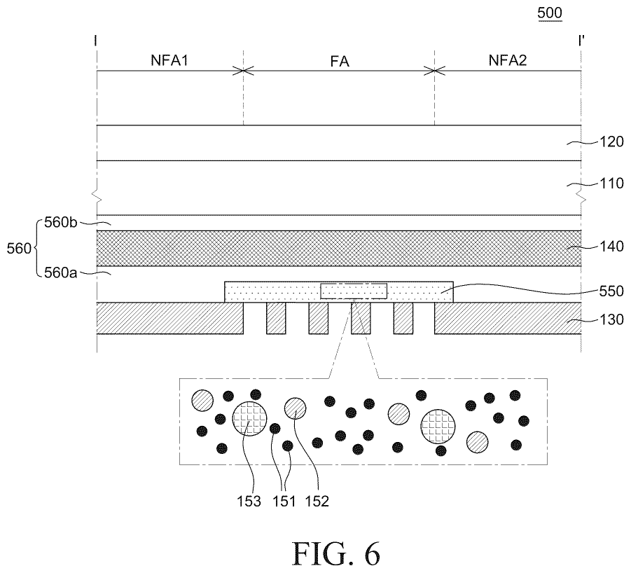

FIG. 6 is a schematic cross-sectional view of a foldable display device according to yet another embodiment of the present disclosure.

Referring to FIG. 6, a foldable display device 500 in this embodiment comprises a display panel 110, a cover window 120, a plate bottom 130, a back plate 140, a black coating layer 550, and an adhesive layer 560. The foldable display device 500 illustrated in FIG. 6 is substantially the same as the foldable display device 400 illustrated in FIG. 5 except that the position and the thickness of the black coating layer 450 differ, and accordingly, their common features are not described or may be briefly described.

In the foldable display device 500, the black coating layer 550 is disposed on the plate bottom 130, and formed only in a portion corresponding to the fold area FA. Since the black coating layer 550 prevents the opening patterns thereunder from being viewed, the opening patterns are disposed only in the fold area FA where the opening patterns are formed, at the plate bottom 130, so that the surface are of the black coating layer 550 can be minimized. Accordingly, a first adhesive layer 560a can be formed only in the non-fold areas NFA1, NFA2 except for the fold area FA. For example, the entire thickness of the foldable display device 500 illustrated in FIG. 6, is less than the entire thickness of the foldable display device 400 illustrated in FIG. 5, having a structure where the black coating layer 450 and the first adhesive layer 160a are stacked, so as to enhance foldable properties.

Hereinafter, effects produced based on the configuration of the adhesive layer in embodiments of the present disclosure and comparative examples are described specifically. However, the embodiments described hereinafter are provided as examples of the present disclosure, and are not intended to limit the scope of the present disclosure.

### EMBODIMENTS AND COMPARATIVE EXAMPLES

A plate bottom that has a thickness of 0.1 mm and on which opening patterns having a size of 5 mm are formed at 0.4 mm intervals, and a back plate that is made of PET and has a thickness of 50 um were prepared. A black coating layer comprised of 20 wt % of acryl resin and 80 wt % of carbon black particles was formed on the lower surface of the back plate. Then the plate bottom and the black coating layer were attached by using a pressure sensitive adhesive (PSA), and a sample of the structure in which the plate bottom, the adhesive, the black coating layer and the back plate were consecutively stacked was manufactured.

At this time, a 1-1 carbon black particle constituting the carbon black particles is a carbon black particle of a unimolecular structure having an average particle size of 36 nm, a 1-2 carbon black particle is an aggregate of carbon black and carbon nano tube having an average particle size of 1.2 um, a second carbon black particle is recycled carbon black having an average particle size of 3.8 um, and a third carbon black particle is bio carbon black having an average particle size of 8 um. Additionally, the content of the 1-1 carbon black particle, the 1-2 carbon black particle, the second carbon black particle and the third carbon black particle included in each embodiment and each comparative example is shown in table 1 hereinafter.

### Experimental Example 1

The thickness, roughness, reflectance and color coordinate of a sample black coating layer in the embodiments and the comparative examples were measured. Results of the measurement are shown in table 1 hereinafter.

Additionally, the reflectance denotes a total of specular reflectance and diffuse reflectance, and specular reflection (or regular reflection) denotes the reflection of light where an angle of lit light and an angle of reflected light are the same, and a rate of light that is scattered in large numbers of directions without causing specular reflection is referred to as diffuse reflectance. A method of measuring a color except for specular reflection light is referred to as a specular component excluded (SCE) method, and if specular reflection light is included to complete an integrating sphere in measurement of a color, this is referred to as a specular component included (SCI) method. In the case where a color is measured based on the SCE method, specular reflection light is completely excluded to measure diffuse refection light only. This is a method in which an observer estimates a color by opening a path of a correlation when the observer views the color of an object. In the SCI method, specular reflectance and diffuse reflectance are included during measurement, and in such a color measurement method, a color can be measured without being affected by a surface state.

### Experimental Example 2

The samples in the embodiments and comparative examples were folded with a bend test jig (radius of curvature 1.5 R). The folded samples were left for 10 days in an environment of 60° C./90% and then unfolded again, and the visibility of the opening patterns formed at the plate bottom was estimated under a fluorescent lamp of 700 lx with the naked eye. The visibility of the opening patterns was graded as very low, low, intermediate and high, based on a degree to which the patterns were viewed. Results of the estimation are shown in table 1 hereinafter.

TABLE 1

| | | | | | | | | | | | Whether |
|---|---|---|---|---|---|---|---|---|---|---|---|
| | Carbon black particle | | | | | | | | | Color | opening |
| | content (wt %) | | | | | | Roughnesss | | Reflectance | coordinate (a*, | patterns are |
| | 1−1 | 1−2 | 2 | 3 | Thickness | | (Ra) | | (SCI/SCE) | b*) | viewed |
| Comparative | 100 | — | — | — | 2 | μm | 12 | nm | 7.00%/0.72% | −7.94/4.08 | High |
| example 1 | | | | | | | | | | | |
| Comparative | 10 | 90 | — | — | 5 | μm | 131 | nm | 6.15%/0.77% | −9.87/4.31 | High |
| example 2 | | | | | | | | | | | |
| Comparative | 80 | 20 | — | — | 3 | μm | 7 | nm | 7.12%/0.73% | −7.94/4.08 | High |
| example 3 | | | | | | | | | | | |
| Comparative | 40 | 60 | — | — | 5 | μm | 83 | nm | 6.13%/0.67% | −10.25/4.45 | High |
| example 4 | | | | | | | | | | | |
| Embodiment 1 | 10 | — | 60 | 30 | 11 | μm | 1.7 | μm | 6.01%/0.63% | −8.75/4.15 | Very low |
| Embodiment 2 | 10 | — | 40 | 50 | 11 | μm | 2.5 | μm | 5.975%/0.61% | −8.91/4.49 | Very low |
| Embodiment 3 | 10 | 30 | 30 | 30 | 11 | μm | 2.3 | μm | 5.97%/0.63% | −8.78/4.45 | Very low |
| Embodiment 4 | 10 | | 50 | 40 | 10 | μm | 2.1 | μm | 6.25%/0.65% | −8.02/4.13 | Very low |
| Embodiment 5 | 40 | — | 30 | 30 | 11 | μm | 2.3 | μm | 6.11%/0.63% | −8.87/4.42 | Very low |
| Referential | 30 | 30 | 20 | 20 | 8 | μm | 1.1 | μm | 5.99%/0.72% | −7.44/3.13 | High |
| example 1 | | | | | | | | | | | |
| Referential | 10 | 50 | 30 | 10 | 7 | μm | 1.7 | μm | 6.03%/0.73% | −7.02/5.22 | High |
| example 2 | | | | | | | | | | | |
| Referential | 10 | 60 | 30 | | 10 | μm | 1.1 | μm | 6.11%/0.63% | −8.45/4.05 | Intermediate |
| example 3 | | | | | | | | | | | |

Referring to Table 1 above, in the samples of embodiments 1-5, the thickness and roughness of the black coating layers are greater than those in the samples of comparative examples 1-4 having no second carbon black particle and third carbon black particle. Accordingly, the visibility of the opening patterns in the embodiments is less than the visibility of the opening patterns in the comparative examples. Additionally, the reflectance of the samples in embodiments 1-5 is less than that of the samples in comparative examples 1-4, and the color coordinate values of the samples in embodiments 1-5 are closer to 0, 0 than those of the samples in comparative examples 1-4, making it clear that deterioration in the visual sensation of black is minimized. Further, referring to embodiments 1-5 and referential examples 1-3, in the case where a total content of the second carbon black particle and the third carbon black particle is 50 wt % or greater with respect to the solid content, the thickness and roughness of the black coating layer can improve, and accordingly, the opening patterns are not visible.

The example embodiments of the present disclosure can also be described as follows:

According to an aspect of the present disclosure, there is provided a foldable display device. The foldable display device comprises a display panel configured to comprise a fold area; a plate bottom configured to support the display panel from a lower portion of the display panel and to comprising a plurality of opening patterns corresponding to the fold area; a back plate disposed between the display panel and the plate bottom; and a black coating layer disposed on at least one surface of the back plate and comprising a first carbon black particle having an average particle size of less than 2 um, a second carbon black particle having an average particle size of 2 um or greater and less than 5 um, and a third carbon black particle having an average particle size of 5 um or greater.

The black coating layer can further comprise a base resin, and with respect to entire weight of the black coating layer, a total content of the first carbon black particle, the second carbon black particle and the third carbon black particle can be 50 wt %-95 wt %.

With respect to entire weight of solids of the first carbon black particle, the second carbon black particle and the third carbon black particle, 10 wt %-50 wt % of the first carbon black particle can be included, 25 wt %-65 wt % of the second carbon black particle can be included, and 25 wt %-65 wt % of the third carbon black particle can be included.

The first carbon black particle can comprise a 1-1 carbon black particle having an average particle size of less than 1 um and a 1-2 carbon black particle having an average particle size of 1 um or greater and less than 2 um.

The 1-1 carbon black particle can be a carbon particle having a unimolecular structure, and the 1-2 carbon black particle can be an aggregate in which carbon black is aggregated.

The 1-2 carbon black particle can be mixed with poly3,4-ethylenedioxythiophene (PEDOT) or carbon nano tube.

The second carbon black particle can be recycled carbon black obtained from a carbon black containing product that is disused.

The second carbon black particle can further comprise at least one impurity comprised of silicon dioxide, zinc oxide and calcium carbonate.

The third carbon black particle can be bio carbon black generated by carbonizing a natural bio material or a natural lignocellulosic material.

A thickness of the black coating layer can be 8 um-15 um.

Surface roughness (Ra) of the black coating layer can be 1.5 um-3 um.

The foldable display device can further comprise a first adhesive layer disposed between the back plate and the plate bottom, and the first adhesive layer can comprise the first carbon black particle, the second carbon black particle and the third carbon black particle.

The foldable display device can further comprise a subsidiary black coating layer disposed between the back plate and the display panel, and the subsidiary black coating layer can comprise the first carbon black particle, the second carbon black particle and the third carbon black particle.

The black coating layer can be disposed to contact the plate bottom and the back plate directly.

The black coating layer can be disposed to correspond only to the fold area.

According to another aspect of the present disclosure, there is provided a foldable display device. The foldable display device comprises: a display panel configured to comprise a fold area; a plate bottom configured to support the display panel from a lower portion of the display panel, and comprising a plurality of opening patterns corresponding to the fold area; and a black coating layer disposed between the display panel and the plate bottom, and comprising a first carbon black particle having an average particle size of less than 2 um, a second carbon black particle having an average particle size of 2 um or greater and less than 5 um, and a third carbon black particle having an average particle size of 5 um or greater.

The foldable display device may further comprise a first adhesive layer disposed between the display panel and the plate bottom, and the first adhesive layer may comprise the first carbon black particle, the second carbon black particle and the third carbon black particle.

The foldable display device may further comprise a subsidiary black coating layer disposed between the black coating layer and the display panel, and the subsidiary black coating layer may comprise the first carbon black particle, the second carbon black particle and the third carbon black particle.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A foldable display device, comprising:
a display panel comprising a fold area;
a plate bottom supporting the display panel from a lower portion of the display panel, and comprising a plurality of opening patterns corresponding to the fold area;
a back plate disposed between the display panel and the plate bottom; and
a black coating layer disposed on at least one surface of the back plate,
wherein the black coating layer comprises:
a first carbon black particle having an average particle size of less than 2 um,
a second carbon black particle having an average particle size ranging from 2 um to less than 5 um, and
a third carbon black particle having an average particle size of 5 um or greater.

2. The foldable display device of claim 1, wherein the black coating layer further comprises a base resin, and
with respect to an entire weight of the black coating layer, a total content of the first carbon black particle, the second carbon black particle and the third carbon black particle is 50 wt %-95 wt %.

3. The foldable display device of claim 1, wherein with respect to an entire weight of solids of the first carbon black particle, the second carbon black particle and the third carbon black particle, 10 wt %-50 wt % of the first carbon black particle is included, 25 wt %-65 wt % of the second carbon black particle is included, and 25 wt %-65 wt % of the third carbon black particle is included.

4. The foldable display device of claim 1, wherein the first carbon black particle comprises a 1-1 carbon black particle having an average particle size of less than 1 um and a 1-2 carbon black particle having an average particle size ranging from 1 um to less than 2 um.

5. The foldable display device of claim 4, wherein the 1-1 carbon black particle is a carbon particle having a unimolecular structure, and the 1-2 carbon black particle is an aggregate in which carbon black is aggregated.

6. The foldable display device of claim 5, wherein the 1-2 carbon black particle is mixed with poly3,4-ethylenedioxythiophene (PEDOT) or carbon nano tube.

7. The foldable display device of claim 1, wherein the second carbon black particle is recycled carbon black obtained from a carbon black containing product that is disused.

8. The foldable display device of claim 7, wherein the second carbon black particle further comprises at least one impurity among silicon dioxide, zinc oxide, or calcium carbonate.

9. The foldable display device of claim 1, wherein the third carbon black particle is bio carbon black generated by carbonizing a natural bio material or a natural lignocellulosic material.

10. The foldable display device of claim 1, wherein a thickness of the black coating layer is about 8 um-15 um.

11. The foldable display device of claim 1, wherein a surface roughness (Ra) of the black coating layer is about 1.5 um-3 um.

12. The foldable display device of claim 1, further comprising a first adhesive layer disposed between the back plate and the plate bottom, and
wherein the first adhesive layer comprises the first carbon black particle, the second carbon black particle and the third carbon black particle.

13. The foldable display device of claim 1, further comprising a subsidiary black coating layer disposed between the back plate and the display panel, and
wherein the subsidiary black coating layer comprises the first carbon black particle, the second carbon black particle and the third carbon black particle.

14. The foldable display device of claim 1, wherein the black coating layer is disposed to contact the plate bottom and the back plate directly.

15. The foldable display device of claim 1, wherein the black coating layer is disposed to correspond only to the fold area.

16. A foldable display device, comprising:
a display panel configured to comprise a fold area;
a plate bottom configured to support the display panel from a lower portion of the display panel, and comprising a plurality of opening patterns corresponding to the fold area; and
a black coating layer disposed between the display panel and the plate bottom, and comprising a first carbon black particle having an average particle size of less than 2 um, a second carbon black particle having an average particle size of 2 um or greater and less than 5 um, and a third carbon black particle having an average particle size of 5 um or greater.

17. The foldable display device of claim 16, further comprising a first adhesive layer disposed between the display panel and the plate bottom,
the first adhesive layer comprising the first carbon black particle, the second carbon black particle and the third carbon black particle.

18. The foldable display device of claim 16, further comprising a subsidiary black coating layer disposed between the black coating layer and the display panel,
the subsidiary black coating layer comprising the first carbon black particle, the second carbon black particle and the third carbon black particle.
